(19) United States
(12) Patent Application Publication
(10) Pub. No.: US 2006/0071349 A1
(43) Pub. Date: Apr. 6, 2006

(54) Semiconductor device and semiconductor device unit

(76) Inventors: Nobuaki Tokushige, Nara-shi (JP); Osamu Nishio, Souraku-gun (JP); Nobuyoshi Awaya, Hiroshima (JP)

Correspondence Address: HARNESS, DICKEY & PIERCE, P.L.C., P.O. BOX 8910, RESTON, VA, 20195, US

(21) Appl. No.: 11/242,870

(22) Filed: Oct. 5, 2005

(30) Foreign Application Priority Data
Oct. 6, 2004 (JP) 2004-293787

(51) Int. Cl. H01L 23/52

(52) U.S. Cl. 257/784

(57) ABSTRACT

A semiconductor device, comprising: a flexible substrate; at least one semiconductor element; at least one electrode for external connection, the element and the electrode being formed on a front surface of the flexible substrate; and at least one wire formed on the front surface to electrically connect the element to the electrode, wherein at least a part of the flexible substrate has a curved form.

### CROSS-REFERENCE TO RELATED APPLICATION

This application is related to Japanese application No. 2004-293787, filed on Oct. 6, 2004 whose priority is claimed under 35 USC § 119, the disclosure of which is incorporated by reference in its entirety.

### BACKGROUND OF THE INVENTION

1. Field of the Invention

The present invention relates to a semiconductor device and a semiconductor device unit. More specifically, it relates to a mounting technique for a semiconductor device having flexibility.

2. Description of the Related Art

The demand for miniaturization and portability of apparatuses like mobile telephones is growing stronger, and in addition, “wearable personal computers” have been announced. Furthermore, interfaces which directly recognize images and sounds, such as 3DMDs (see-through head-mount displays), CCD camera built-in HDs, earphone-type spectacles and earphone-type microphones have been proposed, and it is likely that the market for wearable apparatuses will expand in the future.

As one measure to deal with an increased demand, a method for converting TFT chips for AMLCDs (active matrix displays) into thin films has been proposed (see, e.g., U.S. Pat. No. 5,702,963). According to this method, first, a substrate having an SOI structure where an Si buffer layer 41, a silicon oxide film 42 formed in accordance with a CVD method, a release layer 43 made of a silicon oxynitride film, and an upper Si layer 44 which becomes an element formation layer are layered in this order on an Si substrate 40, as illustrated in FIG. 15A, is used to form a pixel portion (pixel region) 44b and a TFT region 44a of an AMLCD, as illustrated in FIG. 15B.

Next, as illustrated in FIG. 15C, an oxide film 46 which covers the pixel portion 44b and the TFT region 44a is formed so as to form an insulator region 45 between the pixel portion 44b and the TFT region 44a. Subsequently, the oxide film 46 located on the pixel portion 44b is removed. Thereafter, as illustrated in FIG. 15D, a gate electrode 48 is formed on the oxide film 46 in the TFT region 44a, and source/drain regions 49 are formed in the TFT region 44a. In addition, these are covered with an insulating film 50, and contact holes and wires 51 are formed in desired regions in the insulating film 50; thus, a TFT 47 is obtained.

Thereafter, as illustrated in FIG. 15E, an opening 52a is formed in the release layer 43, outside the region that includes the pixel portion 44b and the TFT region 44a. Furthermore, an opening 52b which is greater than the opening 52a is formed in the silicon oxide film 42.

Subsequently, as illustrated in FIG. 15F, a support 53 with which the openings in the silicon oxide film 42 and the release layer 43 are filled is formed from a silicon oxide film. An etchant introducing inlet 54 is formed in the release layer 43, in a region on the inside of the support 53 other than the region that includes the pixel portion 44b and the TFT region 44a. Then, an etchant is introduced through this etchant introducing inlet 54 etch and remove the silicon oxide film 42, thereby forming a hollow 55, as illustrated in FIG. 15G. As a result of this, the pixel portion 44b and the TFT 47 are placed on the release layer 43 that is supported by the support 53.

Next, as illustrated in FIG. 15H, a photosensitive epoxy resin 56 and a non-photosensitive transparent resin film 57 are formed on the entire surface of the resultant substrate. The epoxy resin 56 on the pixel portion 44b and the TFT 47 is irradiated with ultraviolet rays so as to be hardened. The epoxy resin that has not been hardened is removed and, also, the support 53 is cleaved, so that a chip in a thin film form is released.

However, although it is possible to achieve an increase in density of integrated elements by using a semiconductor device in a thin film form that has been fabricated as described above, such a semiconductor device lacks flexibility and ductility and is fragile. Therefore, it is difficult to mount such a semiconductor device freely in a limited small space in a compact apparatus, a portable apparatus, a wearable apparatus and the like.

### SUMMARY OF THE INVENTION

An object of the present invention is to provide a semiconductor device which makes both an increase in the number of functions of a system and an increase in the density of mounted elements through reduction in size possible.

Thus, the present invention provides a semiconductor device, comprising: a flexible substrate; at least one semiconductor element; at least one electrode for external connection, the element and the electrode being formed on a front surface of the flexible substrate; and at least one wire formed on the front surface to electrically connect the element to the electrode, wherein at least a part of the flexible substrate has a curved form.

Also, the present invention provides a semiconductor device unit comprising a plurality of semiconductor devices, wherein the semiconductor devices stack one upon another in spiral forms.

According to the present invention, a semiconductor device is flexible and, therefore, can be mounted in a limited small space in a compact apparatus, a portable apparatus, a wearable apparatus or the like. Consequently, three-dimensional mounting where the number of functions in a system has been increased and freedom of design is great can be achieved.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIGS. 1A and 1B are a plan view and a lateral sectional view that illustrate a semiconductor device according to a first embodiment of the present invention;

FIGS. 2A and 2B are a plan view and a lateral sectional view that illustrate a semiconductor device according to a second embodiment of the present invention;

FIGS. 3A and 3B are a front view and a perspective view that illustrate a semiconductor device according to a third embodiment of the present invention;

FIG. 4 illustrates a state where a plurality of cylindrical semiconductor devices according to the third embodiment are arranged in proximity to each other;

FIG. 5 is a perspective view that illustrates a semiconductor device according to a fourth embodiment of the present invention;

FIG. 6 is a perspective view that illustrates a semiconductor device according to a fifth embodiment of the present invention;

FIGS. 7A and 7B are a plan view and a lateral sectional view that illustrate a semiconductor device according to a sixth embodiment of the present invention;

FIGS. 8A and 8B are a plan view and a lateral sectional view that illustrate a semiconductor device according to a seventh embodiment of the present invention;

FIGS. 9A and 9B are a front view and a perspective view that illustrate a semiconductor device according to an eighth embodiment of the present invention;

FIG. 10 illustrates a state where a plurality of semiconductor devices as that according to the eighth embodiment are installed adjacent to each other and stacked in a plurality of stacks;

FIG. 11 is a perspective view that illustrates a semiconductor device according to a ninth embodiment of the present invention;

FIG. 12 is a perspective view that illustrates a semiconductor device according to a tenth embodiment of the present invention;

FIG. 13 is a lateral sectional view that illustrates a state where the semiconductor device according to the first embodiment is installed;

FIG. 14 illustrates a state where the semiconductor device according to the eighth embodiment is installed; and

FIGS. 15A to 15H illustrate manufacturing steps of a conventional semiconductor device.

### DESCRIPTION OF THE PREFERRED EMBODIMENTS

A semiconductor device according to the present invention, comprising: a flexible substrate; at least one semiconductor element; at least one electrode for external connection, the element and the electrode being formed on a front surface of the flexible substrate; and at least one wire formed on the front surface to electrically connect the element to the electrode.

According to the present invention, the flexible substrate is not particularly limited, as long as it has flexibility, and semiconductor elements (semiconductor chips) or printed wires can be formed on a front surface thereof. A substrate made of a resin, such as one made of a polyimide film, a polyester film or the like, which is generally utilized as a printed circuit board, is appropriate for use as the flexible substrate.

In addition, a semiconductor substrate can be used as the flexible substrate, as long as necessary and sufficient flexibility can be attained by adjusting the film thickness and the curvature radius. A variety of substrates, including, e.g., element semiconductor substrates such as silicon and germanium, compound semiconductor substrate such as GaAs and InGaAs, insulating semiconductor oxide substrates and SOI substrates can be used as the semiconductor substrate. In particular, single crystal silicon substrates or polycrystal silicon substrates are preferable, and specifically, single crystal silicon substrates are preferable. It is preferable for the semiconductor substrate to have a relatively low resistance (e.g., about 20 Ωcm or less, preferably about 10 Ωcm), resulting from doping of N-type impurities such as phosphorous or arsenic or P-type impurities such as boron. Here, in the case where a semiconductor substrate or an SOI substrate is used as the flexible substrate, it is possible to directly form semiconductor elements on the substrate.

As described above, semiconductor elements (chips) that have been fabricated in advance may be made to adhere to the flexible substrate, or may be formed on the semiconductor substrate as described above. Alternatively, semiconductor elements may be formed on a semiconductor substrate on which a semiconductor layer has been formed, e.g., a so-called epitaxial substrate where about 1 μm of a p-type or n-type epitaxial silicon layer is layered on the front surface of an n-type or p-type silicon substrate, or may be formed on a substrate that is not made of a semiconductor, on which a semiconductor layer is formed, e.g., an SOI substrate.

The semiconductor elements conventionally form a variety of circuits such as memories, peripheral circuits and logic circuits, and include a variety of elements such as transistors, capacitors and resistors. In addition, a variety of films such as element isolation films, interlayer insulating films and wires for isolating or connecting these elements may be formed. The size of a semiconductor element region is not particularly limited, and can be appropriately adjusted in accordance with the size, functions, applications and the like of the semiconductor device to be obtained.

The material for the electrodes is not particularly limited, and a material that is generally utilized in this field, such as aluminum or silver, can be used.

The material for the wires is not particularly limited, and a material that is generally utilized in this field, such as copper or nickel, can be used.

In the semiconductor device according to the present invention, the flexible substrate has a first end and a second end opposed to the first end, and has a feature in that the flexible substrate that is provided with the at least one semiconductor element, electrode and wire, respectively, is at least partially held in a curved form.

Here, according to the present invention, “the flexible substrate is at least partially held in a curved form” means a state where part or the entirety of the flexible substrate is curved at least while the semiconductor device is in use. In addition, “a curved form” means a form where part or the entirety of the flexible substrate is curved in such a manner as to form a U shape, an S shape, a C shape, a waved shape, a cylindrical shape, a spiral shape or the like.

It is preferable for the curved form of the flexible substrate to be a cylindrical form so that the first end abuts the second end.

As a result of this, the flexible substrate that has been rounded into a cylindrical form becomes a rigid body where the mechanical strength against bending is higher, therefore, the semiconductor elements can be protected from external force when the semiconductor device is transported or assembled in an electronic apparatus, when the electronic apparatus is in use, and the like. Furthermore, a reduction in the space required for installing the semiconductor device in an electronic apparatus can be achieved. In other words, a greater number of semiconductor elements can be installed in the same space, and an increase in the number of functions can be achieved. In this case, the first and second ends of the flexible substrate can be made to adhere to each other with, e.g., an adhesive, so as to be held in a cylindrical form.

A more preferable curved form for the flexible substrate is a spiral structure so that the first end forms a periphery of the structure and the second end forms a center of the structure.

As a result of this, the mechanical strength against the aforementioned bending and the number of installable semiconductor elements per space unit can further be increased.

In the case of this spiral structure, it is preferable for the at least one electrode is placed adjacent to the first end of the flexible substrate, from the point of view of ease of electrical connection (e.g., connection through lead wires) between another electronic component of the electronic apparatus and the semiconductor device according to the present invention.

Furthermore, the flexible substrate may be provided with a plurality of protrusions on the front surface between the first end and the second end, so that the aforementioned spiral structure has a overlap portion, the overlap portion having a gap formed by the protrusions. As a result of this, scratching on the front surface caused by friction of the elements can be reduced when the flexible substrate is rolled into a spiral, and this is preferable for increasing the heat releasing properties of the elements. In this case, the first end outside of the flexible substrate, and a portion of a rear surface of the flexible substrate which can be made to make contact with this first end can be made to adhere to each other with, e.g., an adhesive, so that the flexible substrate can be held in a the spiral structure.

Furthermore, in the spiral structure, a plurality of semiconductor devices, each of which is the same as the aforementioned semiconductor device, may stack one upon another in spiral form. As a result of this, a greater number of semiconductor elements can be installed in the same space.

In the semiconductor device having a cylindrical or spiral structure, the conditions for rolling the flexible substrate more compactly depend on a variety of factors such as the material of the flexible substrate, the length and the thickness of the flexible substrate, which determine the circumference, the size, number and arrangement of the semiconductor elements which are mounted on the flexible substrate, and the thickness of the wires, whereas the size and the thickness of the semiconductor elements, wires and electrodes are small (e.g., the size of the semiconductor elements is 1 mm×1 mm, and the thickness is 300 μm), in comparison with the size and the thickness of the flexible substrate. Therefore, rolling of the semiconductor device depends almost completely on the material (flexibility) of the flexible substrate, as well as the length and the thickness of the flexible substrate, which determine the circumference.

In the case where a flexible substrate made of a polyimide film having a length of 10 mm, a width of 10 mm and a thickness of 500 μm is assumed, for example, it is possible to roll the flexible substrate along the length into a roll of which the diameter is as small as about 3 mm. In addition, in the case where the flexible substrate is made of a silicon substrate having a length of 10 mm, a width of 10 mm and a thickness of 300 μm, it is possible to roll the flexible substrate along the length into a roll of which the diameter is as small as about 3 mm.

Furthermore, the semiconductor device according to the present invention may have at least one rear wire formed on the rear surface of the flexible substrate, the rear wire being connected to the at least one electrode. As a result of this, a plurality of semiconductor devices having a cylindrical or spiral structure can be installed laterally adjacent to each other or in a stacked form, so that rear wires on the rear surface of particular adjacent semiconductor devices are made to make contact with each other. Thus, semiconductor elements of the adjacent semiconductor devices can be electrically connected to each other.

In the following, preferred embodiments of the semiconductor device according to the present invention will be described in detail, with reference to the drawings. Here, the present invention is not limited to the embodiments.

### First Embodiment

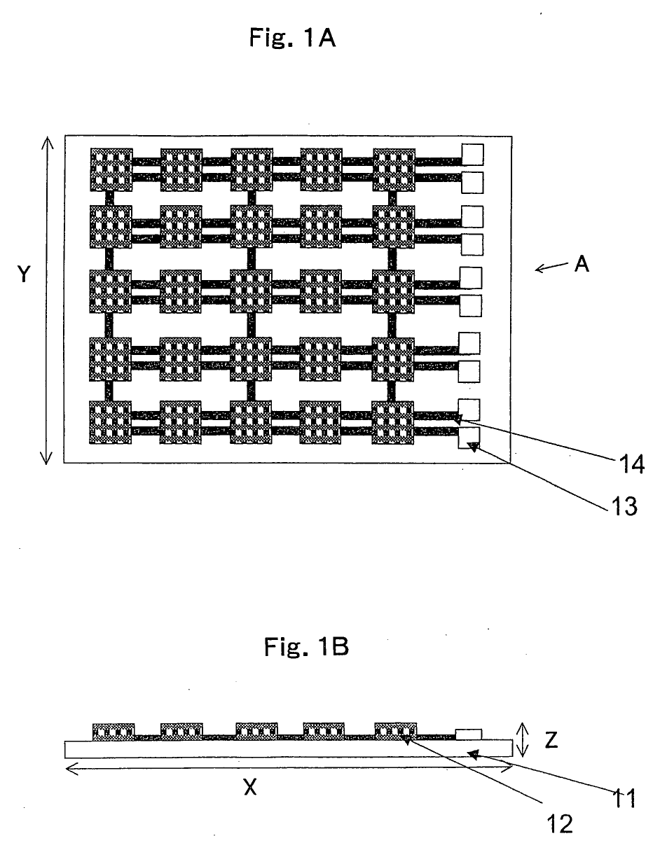

FIGS. 1A and 1B are a plan view and a lateral sectional view that illustrate a semiconductor device according to a first embodiment of the present invention.

A semiconductor device A of this embodiment includes a flexible substrate 11 which is rectangular in a plan view, a plurality of electrodes for external connections which are made of Al along a first end on the front surface of the flexible substrate 11, i.e., pad electrodes 13, a plurality of semiconductor elements 12 which are formed in matrix form on the front surface of the flexible substrate 11, and a plurality of wires 14 which are made of Cu for electrical connection between the semiconductor elements 12 and between the semiconductor elements 12 and the pad electrodes 13 on the front surface of the flexible substrate 11.

Next, a manufacturing method of the semiconductor device of this embodiment is described with reference to FIG. 1.

First, a plurality of pieces which are aligned in a straight line at predetermined intervals along the first end of the front surface of the flexible substrate 11 are printed with an Al paste and baked according to a known method, so as to form the pad electrodes 13.

Next, a plurality of semiconductor elements 12 are fixed to the front surface of the flexible substrate 11 in matrix form, and this becomes an element region. The fixing of the semiconductor elements 12 to the flexible substrate 11 can be carried out by adopting a method for adhesion using an adhesive or a solder. Here, desired semiconductor elements, such as transistors, capacitors and resistors which have been fabricated in advance in a chip form, in accordance with the semiconductor device to be obtained, are used as the semiconductor elements 12, and each element is fixed in a predetermined place.

Next, the wires 14 are formed of Cu in accordance with a known method, such as plating or printing.

### Second Embodiment

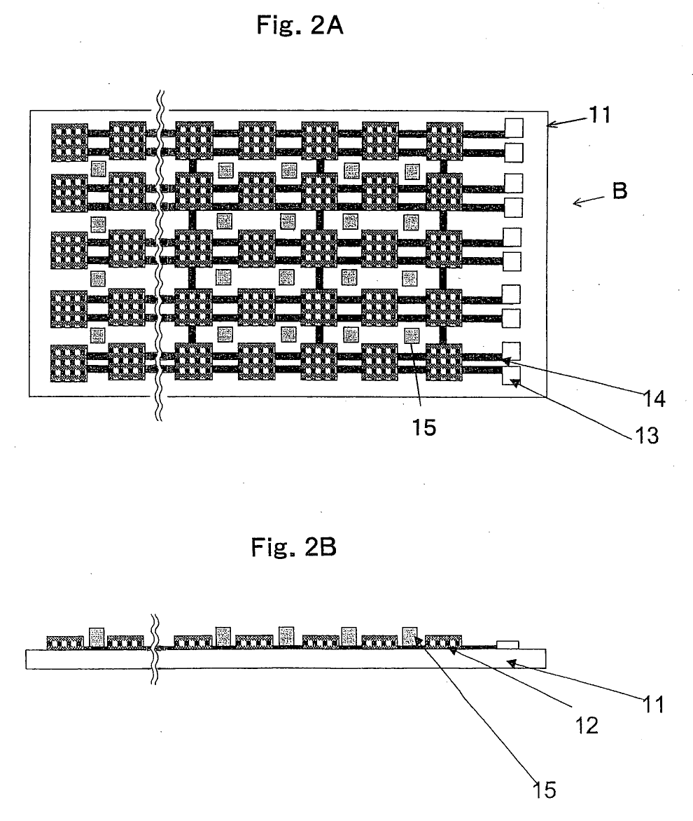

FIGS. 2A and 2B are a plan view and a lateral sectional view that illustrate a semiconductor device according to a second embodiment of the present invention.

A semiconductor device B of this embodiment is different from the semiconductor device of the first embodiment in that a plurality of protrusions 15 are formed in spaces between the respective semiconductor elements 12 and the wires 14 on the front surface of the flexible substrate 11, and the other configurations are the same as those in the first embodiment. An appropriate material can be selected for these protrusions 15 from plastics having insulating properties and metals having conductivity, in accordance with conditions such as adhesiveness to the flexible substrate 11 or required mechanical strength, and these protrusions may be made to adhere with an adhesive or a solder.

### Third Embodiment

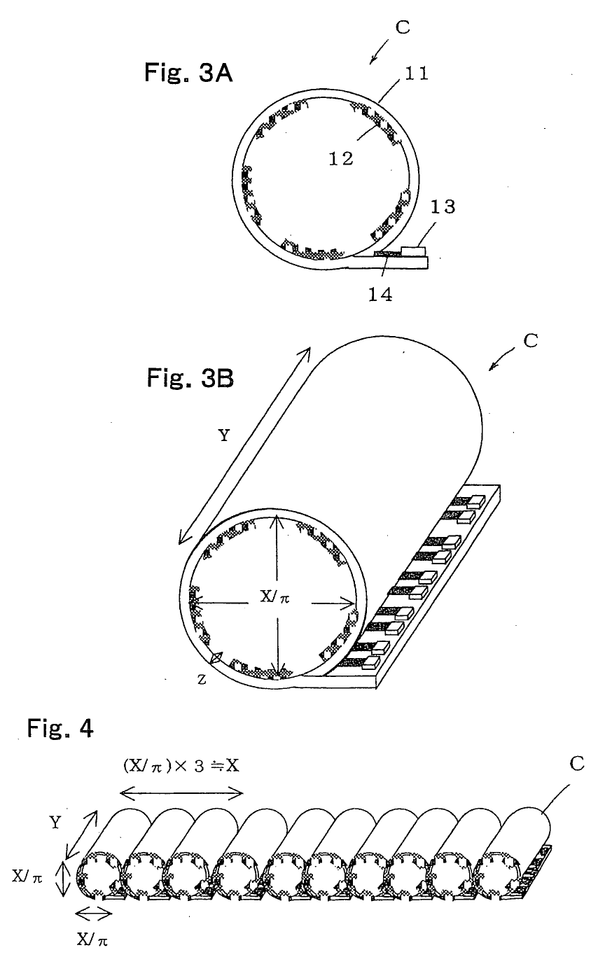

FIGS. 3A and 3B are a front view and a perspective view that illustrate a semiconductor device according to a third embodiment of the present invention.

A semiconductor device C of this embodiment is obtained by rolling and holding the semiconductor device of the first embodiment in a cylindrical form. At the time of the fabrication of this cylindrical semiconductor device, a method for rolling the flexible substrate 11 using a rod as a core can be used. The flexible substrate 11 can be rolled in a state where the pad electrodes 13 are exposed on the outside and, thereafter, the cylindrical form can be held be means of adhesion.

The flexible substrate 11 having a length of X and a width of Y before rolling is rolled into this cylindrical semiconductor device C having a diameter of approximately X/π.

FIG. 4 illustrates a state where a plurality of cylindrical semiconductor devices are arranged in proximity to each other. As illustrated in this figure, the area occupied by the semiconductor elements (chips) has been reduced to about ⅓ in the direction of the length, and the mounting area can be reduced, in comparison with planar flexible substrates 11. Here, the height is X/π, which is greater than the thickness Z (see FIGS. 1A and 1B) of a flexible substrate 11 before rolling, and the flexible substrates 11 have become rigid bodies by being rolled, and the mechanical strength against bending has been increased. Therefore, the flexible substrates 11 can be appropriately arranged as a chip in an electronic apparatus or the like, without additional processing, such as special mounting.

### Fourth Embodiment

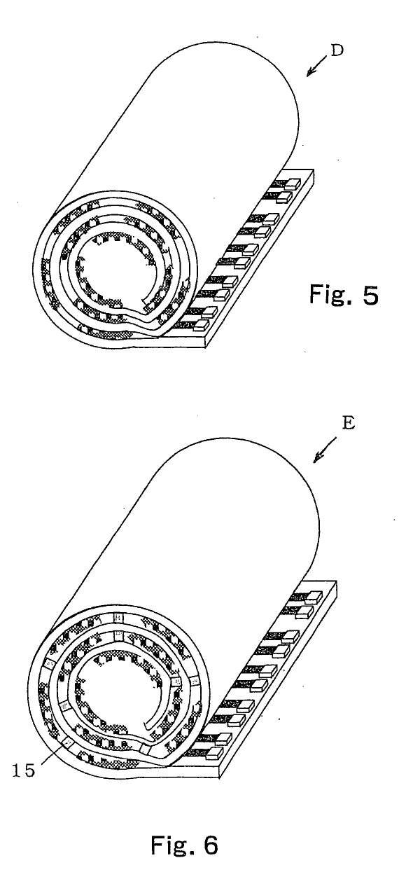

FIG. 5 is a perspective view that illustrates a semiconductor device according to a fourth embodiment of the present invention.

A semiconductor device D of this embodiment is obtained by rolling and holding the semiconductor device of the second embodiment in a spiral. At the time of the fabrication of the semiconductor device having this spiral structure, a method for rolling a flexible substrate 11 using a rod as a core can be used. The flexible substrate 11 can be rolled in a state where pad electrodes 13 are exposed on the outside and, thereafter, the spiral structure can be held by means of adhesion.

As a result of this, the mounting area can further be reduced, in comparison with planar flexible substrates 11, and it becomes possible to further increase the mechanical strength against bending.

### Fifth Embodiment

FIG. 6 is a perspective view that illustrates a semiconductor device according to a fifth embodiment of the present invention.

A semiconductor device E of this embodiment is obtained by rolling and holding the semiconductor device of the third embodiment, and the other configurations are the same as those in the third embodiment. At the time of the fabrication of the semiconductor device E having this spiral structure, the protrusions 15 on the front surface of the flexible substrate 11 make contact with the rear front surface of the flexible substrate 11 which is rolled. Therefore, scratches on the surface of the chip resulting from friction of the semiconductor elements 12 at the time of rolling can be reduced and, also, hollows are formed inside the spiral structure, so that an effect of improving the heat releasing property of the chip can be attained in addition to the effects in the fourth embodiment.

### Sixth Embodiment

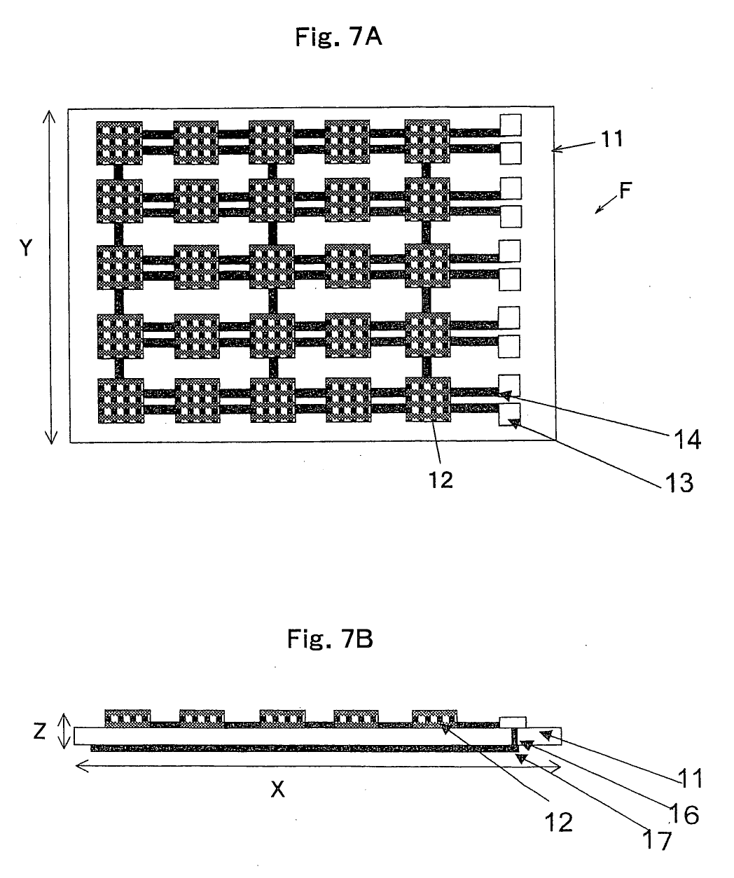

FIGS. 7A and 7B are a plan view and a lateral sectional view that illustrate a semiconductor device according to a sixth embodiment of the present invention.

A semiconductor device F of this embodiment is different from the semiconductor device of the first embodiment in that a plurality of rear wires 17 are formed on the rear surface of the flexible substrate 11, and buried conductive layers 16 are provided in through holes that are formed at positions beneath the respective pad electrodes 13 in the flexible substrate 11, so that the rear wires 17 and the buried conductive layers 16 are electrically connected to each other. The other configurations are the same as those in the first embodiment. The wiring pattern of these rear wires 17 can be stripes which are respectively electrically connected to the pad electrodes 13 and extend in the direction of the length (X direction).

At the time of the fabrication of the semiconductor device F of this embodiment, the semiconductor device of the first embodiment is fabricated. Thereafter, through holes are formed from the rear surface of the flexible substrate 11 toward the pad electrodes 13 and, then, the buried conductive layers 16 are formed of metal such as Cu or Ag in accordance with a known method such as plating or printing. Thereafter, the rear wires 17 are formed on the rear surface of the flexible substrate 11 in accordance with a known method such as plating or printing, so as to be electrically connected to the buried conductive layers 16. Alternatively, in accordance with another manufacturing method, the buried conductive layers 16 and the rear wires 17 may be formed in advance on the rear surface of the flexible substrate 11 and, thereafter, the semiconductor elements 12, the electrodes 13 and the wires 14 may be formed on the front surface of the flexible substrate 11.

### Seventh Embodiment

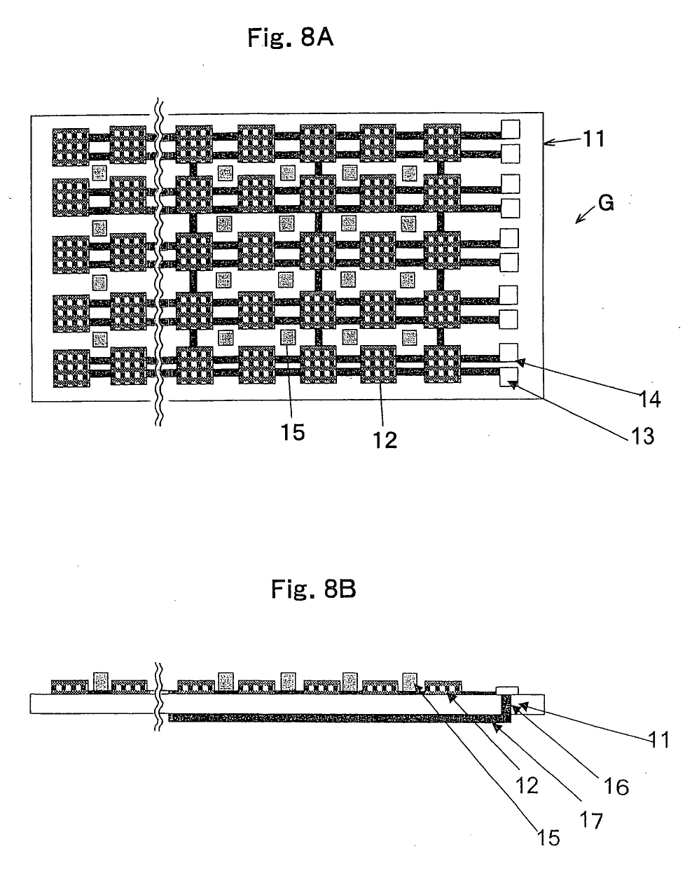

FIGS. 8A and 8B are a plan view and a lateral sectional view that illustrate a semiconductor device according to a seventh embodiment of the present invention.

A semiconductor device G of this embodiment is different from the semiconductor device of the sixth embodiment in that the plurality of protrusions 15 are formed in spaces between the respective semiconductor elements 12 and the wires 14 on the front surface of the flexible substrate 11 in the same manner as in the second embodiment. The other configurations are the same as those in the sixth embodiment.

### Eighth Embodiment

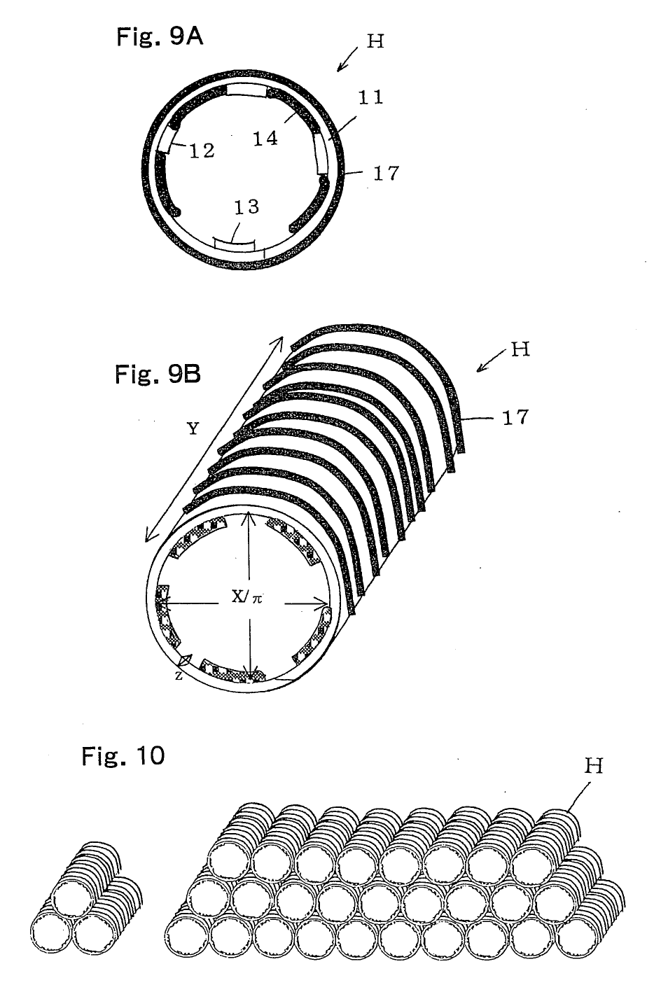

FIGS. 9A and 9B are a front view and a perspective view that illustrate a semiconductor device according to an eighth embodiment of the present invention.

A semiconductor device H of this embodiment is obtained by rolling and holding the semiconductor device of the sixth embodiment in a cylindrical form. At the time of the fabrication of this cylindrical semiconductor device, a method for rolling a flexible substrate 11 using a rod as a core, as described above, and for holding it in a cylindrical form by means of adhesion can be used. In this case, the flexible substrate 11 may be rolled in a state where pad electrodes 13 are exposed on the outside, or, as illustrated in FIGS. 9A and 9B, the two end surfaces of the flexible substrate 11 may be made to adhere to each other and the pad electrodes 13 arranged inside the cylinder.

As a result of this configuration, when a plurality of semiconductor devices H are installed adjacent to each other or stacked in a plurality of stacks, as illustrated in FIG. 10, the semiconductor elements 12 of the respective adjacent semiconductor devices are electrically connected to each other via rear wires 17, pad electrodes 13 and wires 14. Accordingly, the additional task of special wiring becomes unnecessary.

### Ninth Embodiment

FIG. 11 is a perspective view that illustrates a semiconductor device according to a ninth embodiment of the present invention.

A semiconductor device I of this embodiment is obtained by rolling and holding the semiconductor device of the sixth embodiment in a spiral. In this case, the flexible substrate 11 may be rolled in a state where pad electrodes 13 are exposed on the outside, or the flexible substrate 11 may be completely rolled with the pad electrodes 13 making contact with the rear surface of the flexible substrate 11, as illustrated in FIG. 11.

As a result of this configuration, both the aforementioned advantages of the spiral structure and the aforementioned advantages of the provision of the rear wire on the rear surface can be attained.

### Tenth Embodiment

FIG. 12 is a perspective view that illustrates a semiconductor device according to a tenth embodiment of the present invention.

A semiconductor device J of this embodiment is obtained by rolling and holding the semiconductor device of the seventh embodiment in a spiral. In this case, the flexible substrate 11 may be rolled in a state where pad electrodes 13 are exposed on the outside, or the flexible substrate 11 may be completely rolled with the pad electrodes 13 making contact with the rear surface of the flexible substrate 11, as illustrated in FIG. 12.

As a result of this configuration, the aforementioned advantages of the spiral structure, the aforementioned advantages of the provision of the rear wire on the rear surface, and the aforementioned advantages of the provision of the protrusions 15 can be attained.

[Others]

The present invention can provide a device (not illustrated) where a plurality of semiconductor devices having any of the structures illustrated in FIGS. 1A and 1B, 2A and 2B, 7A and 7B, and 8A and 8B are made to overlap each other and held in a spiral structure. More specifically, a plurality of semiconductor devices are prepared to the first embodiment, for example, and the semiconductor devices stack one upon another, and this layered body is rolled into a spiral in accordance with the aforementioned method. Here, the respective semiconductor devices can be integrated by means of adhesion or the like, in order to maintain the spiral structure.

[Description of Condition in Use]

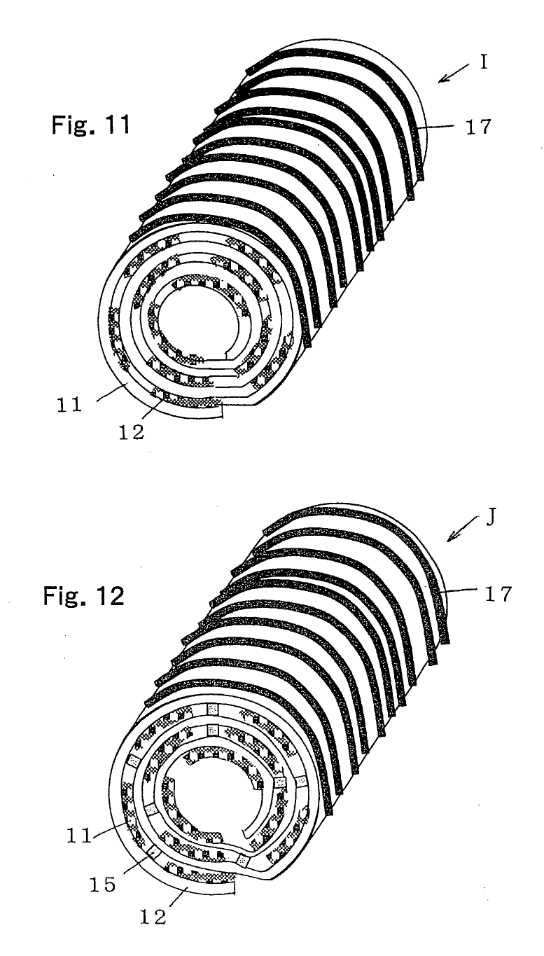

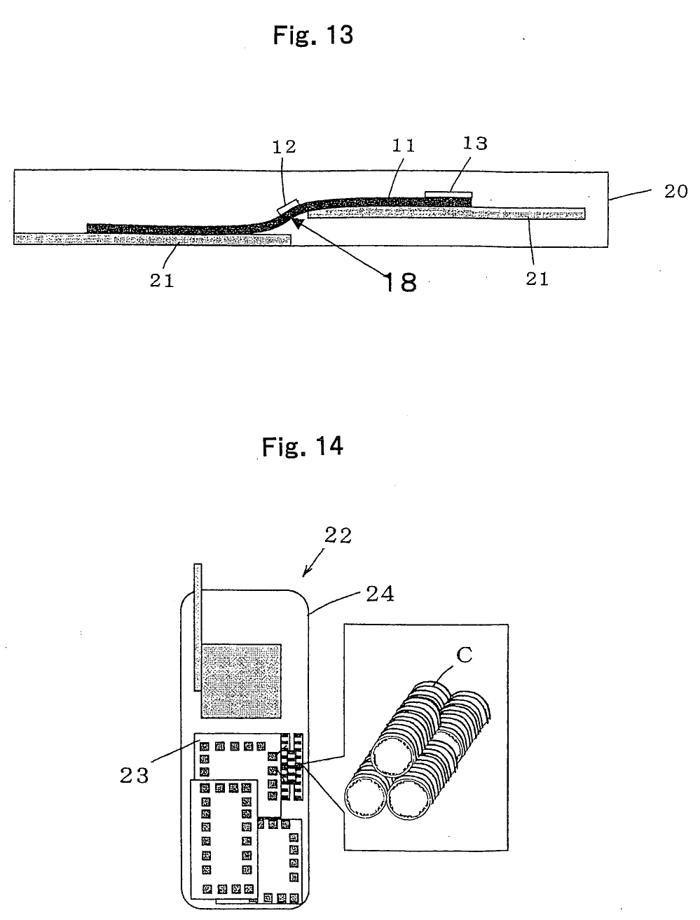

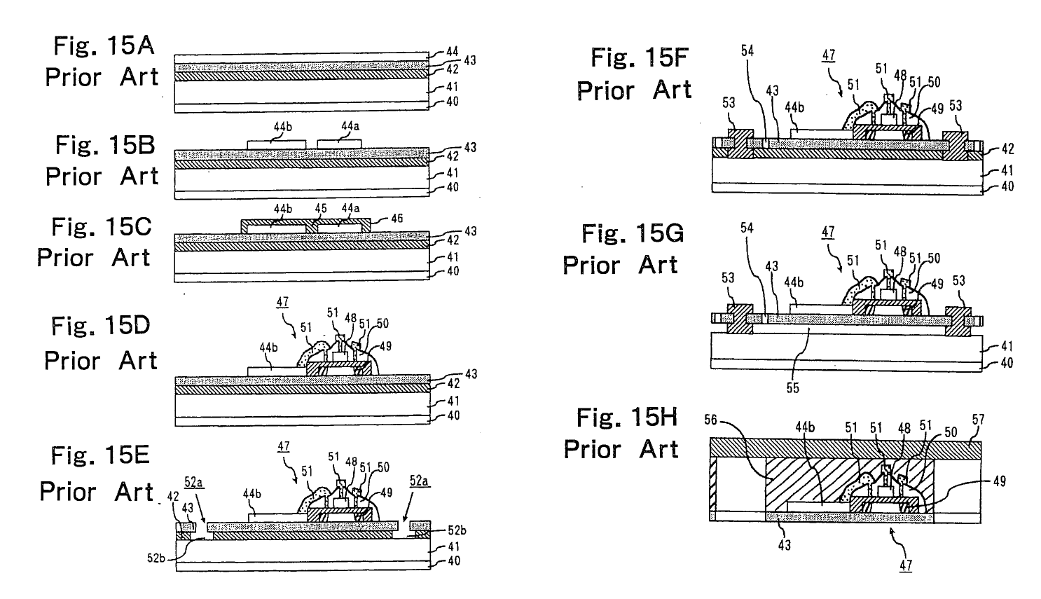

FIG. 13 is a lateral sectional view that illustrates a state where the semiconductor device according to the first embodiment is installed. In this case where the semiconductor device of the present invention is used, a chip (semiconductor element 12) can be placed in a step portion 18 between existing printed substrates 21 without requiring a great change in the design of the apparatus, such as the design of the body, when a module is added to a thin portable apparatus 20 such as a mobile telephone.

In addition, FIG. 14 illustrates a state where the semiconductor device according to the eighth embodiment is installed. In this case, cylindrical semiconductor devices can be placed in a gap between an existing printed substrate 23 and a case 24 of, e.g., a mobile telephone 22. At this time, the semiconductor devices can be placed in three dimensions in accordance with the gap, so that the space can be effectively used. Here, semiconductor devices having a spiral structure can be used in the same manner.

A semiconductor device according to the present invention is suitable for a variety of electronic apparatuses, particularly, mobile telephones and laptop personal computers, where portability and miniaturization are particularly required, as well as for interfaces which directly recognize images and sounds, such as 3DMDs (see-through head-mount displays), CCD camera built-in HDs, earphone-type spectacles and earphone-type microphones.

What is claimed is:

1. A semiconductor device, comprising:
a flexible substrate;
at least one semiconductor element;
at least one electrode for external connection, the element and the electrode being formed on a front surface of the flexible substrate; and
at least one wire formed on the front surface to electrically connect the element to the electrode,
wherein at least a part of the flexible substrate has a curved form.

2. The device of claim 1, wherein the substrate has a first end and a second end opposed to the first end, and the substrate has a cylindrical form so that the first end abuts the second end.

3. The device of claim 1, wherein the substrate has a first end and a second end opposed to the first end, and the substrate has a spiral structure so that the first end forms a periphery of the structure and the second end forms a center of the structure.

4. The device of claim 3, wherein the at least one electrode is placed adjacent to the first end.

5. The device of claim 3, wherein the substrate has a plurality of protrusions over the front surface, and the spiral structure has a overlap portion, the overlap portion having a gap formed by the protrusions.

6. The device of claim 1, wherein the substrate comprises a semiconductor substrate.

7. The device of claim 1, wherein the at least one semiconductor element and the at least one electrode includes a plurality of semiconductor elements and a plurality of electrodes, respectively, and the at least one wire includes a plurality of wires, the plurality of wire including wires for connecting the semiconductor elements to each other and wires for connecting the semiconductor elements to the electrodes.

8. The device of claim 1, further comprising at least one rear wire formed on a rear surface of the substrate, the rear wire being electrically connected to the at least one electrode.

9. A semiconductor device unit comprising a plurality of semiconductor devices, wherein the semiconductor devices stack one upon another in spiral forms.
